(19) United States
(12) Patent Application Publication
(10) Pub. No.: US 2026/0331934 A1
(43) Pub. Date: Oct. 22, 2026

(54) MODULAR POWER SOURCE AND SYSTEMS

(71) Applicant: MARLEX Engineering Inc., Ancaster (CA)

(72) Inventors: Uwe Dirk Schaible, Ancaster (CA); Steven Craig Hanes, Ancaster (CA)

(21) Appl. No.: 19/458,202

(22) Filed: Jan. 23, 2026

Related U.S. Application Data
(60) Provisional application No. 63/748,720, filed on Jan. 23, 2025.

(51) Int. Cl. H02J 7/70; B60L 53/30; B60L 53/302; B60L 53/62; H01M 10/46; H01M 50/244; H01M 50/583; H02J 7/60; H02J 7/80; H05K 5/02

(52) U.S. Cl. CPC H02J 7/70; B60L 53/302; B60L 53/305; B60L 53/62; H01M 10/46; H01M 50/244; H01M 50/583; H02J 7/60; H02J 7/80; H05K 5/0213; H05K 5/0226; H01M 2220/30

(57) ABSTRACT

Modular power sources and systems are provided. The modular power source includes a housing, a power module configured for providing a variable output of power, and at least one modular battery unit. The housing includes a frame constructed of powder-coated steel to create at least one level; two heavy-duty casters attached at a first end of the frame; two airless tires attached at a second end of the frame; a cooling vent system; a hinged access panel; and a push handle. The power module includes an AC charging input; and a plurality of AC power outputs. A power supply system includes an equipment configured to receive electrical power; and a modular power source configured to provide electrical power to the equipment.

### TECHNICAL FIELD

The following relates generally to construction equipment, and, in particular to a modular and portable power source for various construction applications.

### INTRODUCTION

Different types of construction equipment can have different power requirements.

As a result, construction teams may be required to bring several different types of power supply equipment to job sites which are then able to provide the necessary power for equipment such as welders, plasma cutters, lighting, and others.

However, this can be an inefficient and expensive approach since bringing several power delivery machines can result in other needed machines being left behind, or multiple trips being required to bring all of the needed equipment.

Accordingly, there is a need for improved systems, methods and devices that overcome at least some of the disadvantages of existing techniques.

This background information is provided to reveal information believed by the applicant to be of possible relevance to the present disclosure. No admission is necessarily intended, nor should be construed, that any of the preceding information constitutes prior art against the present disclosure.

### SUMMARY

A modular power source is provided. The modular power source includes a housing, a power module configured for providing a variable output of power, and at least one modular battery unit. The housing includes a frame constructed of powder-coated steel to create at least one level, two heavy-duty casters attached at a first end of the frame, two airless tires attached at a second end of the frame, a cooling vent system, a hinged access panel, and a push handle. The power module includes an AC charging input, and a plurality of AC power outlets.

In an embodiment, the power module further includes at least one of an antenna connector, an on-off selector switch, a display, one or more communication ports, a battery charge monitor configured for monitoring real-time usage and accurately measuring a battery capacity, and one or more circuit breakers.

In an embodiment, the one of more circuit breakers includes at least one of a charge circuit breaker, a push-to-reset circuit breaker, a welder circuit breaker.

In an embodiment, the display uses color to indicate a remaining battery capacity.

In an embodiment, the at least one modular battery unit is one of heated, and not heated.

In an embodiment, the at least one modular battery unit includes forklift pockets to facilitate removal of the at least one modular battery unit.

In an embodiment, the at least one modular battery unit includes a forklift insertion guide to facilitate removal of the at least one modular battery unit.

In an embodiment, the housing further includes at least one fastener for fastening down the at least one modular battery unit.

In an embodiment, the modular power source further includes an integrated antenna for wireless communications.

In an embodiment, the modular power source further includes a thermal management system.

A power supply system is provided. The power supply system includes an equipment configured to receive electrical power; and a power source configured to provide electrical power to the equipment. The power source includes a housing, a power module configured for providing a variable output of power, and at least one modular battery unit. The housing includes a frame constructed of powder-coated steel to create at least one level, two heavy-duty casters attached at a first end of the frame, two airless tires attached at a second end of the frame, a cooling vent system, a hinged access panel, and a push handle. The power module includes an AC charging input, and a plurality of AC power outlets.

In an embodiment, the power source is in communication with the equipment.

In an embodiment, the equipment includes industrial power equipment.

In an embodiment, the industrial power equipment includes at least one of: a welder; and a plasma cutter

In an embodiment, the equipment includes at least one of: an electric vehicle; a hybrid vehicle; and a charging station.

In an embodiment, the equipment includes a liquid pump control unit.

In an embodiment, the equipment includes at least one of: a cellular modem-based internet access point; and a satellite modem-based internet access point.

In an embodiment, the equipment includes a lighting management system.

In an embodiment, the equipment includes video and sensing equipment for remote monitoring applications.

In an embodiment, the equipment includes a power grid.

Other aspects and features will become apparent, to those ordinarily skilled in the art, upon review of the following description of some exemplary embodiments.

### BRIEF DESCRIPTION OF THE DRAWINGS

The drawings included herewith are for illustrating various examples of articles, methods, and apparatuses of the present specification. In the drawings:

FIGS. 1A and 1B are diagrams of a modular power source, according to an embodiment;

FIG. 2 is an exploded view of a modular battery unit, according to an embodiment;

FIG. 3A is a diagram of self-heating batteries, according to an embodiment;

FIG. 3B is an alternate view of a modular battery unit, according to an embodiment;

FIG. 4A is a diagram of non-self-heating batteries, according to an embodiment;

FIG. 4B is a diagram of a modular power source with non-self-heating batteries, according to an embodiment;

FIG. 5 is a diagram of a power module, according to an embodiment; and

FIG. 6 is a schematic diagram of an example electronic device, according to an embodiment.

### DETAILED DESCRIPTION

Various apparatuses or processes will be described below to provide an example of each claimed embodiment. No embodiment described below limits any claimed embodiment and any claimed embodiment may cover processes or apparatuses that differ from those described below. The claimed embodiments are not limited to apparatuses or processes having all of the features of any one apparatus or process described below or to features common to multiple or all of the apparatuses described below.

As used herein, the term “about” should be read as including variation from the nominal value, for example, a +/−10% variation from the nominal value. It is to be understood that such a variation is always included in a given value provided herein, whether or not it is specifically referred to.

One or more systems described herein may be implemented in computer programs executing on programmable computers, each comprising at least one processor, a data storage system (including volatile and non-volatile memory and/or storage elements), at least one input device, and at least one output device. For example, and without limitation, the programmable computer may be an embedded system, a programmable logic controller, a mainframe computer, server, and personal computer, cloud-based program or system, laptop, personal data assistant, cellular telephone, smartphone, or tablet device.

Each program is preferably implemented in a high-level procedural or object-oriented programming and/or scripting language to communicate with a computer system. However, the programs can be implemented in assembly or machine language, if desired. In any case, the language may be a compiled or interpreted language. Each such computer program is preferably stored on a storage media or a device readable by a general or special purpose programmable computer for configuring and operating the computer when the storage media or device is read by the computer to perform the procedures described herein.

A description of an embodiment with several components in communication with each other does not imply that all such components are required. On the contrary, a variety of optional components are described to illustrate the wide variety of possible embodiments of the present disclosure.

Further, although process steps, method steps, algorithms or the like may be described (in the disclosure and/or in the claims) in a sequential order, such processes, methods and algorithms may be configured to work in alternate orders. In other words, any sequence or order of steps that may be described does not necessarily indicate a requirement that the steps be performed in that order. The steps of processes described herein may be performed in any order that is practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device / article may be used in place of the more than one device or article.

The following relates generally to construction equipment, and more particularly to a modular and portable power source for various construction applications.

The present disclosure relates to a power source having a removable intelligent power module, a removable intelligent modular battery, and a structure that can be reconfigured as a silent clean energy power supply for welders or other electrical equipment.

Such a modular power source is designed to serve as a power source for electric devices at construction sites where access to AC power may be unavailable, in particular, for applications like welding or cutting. The modular power source provides an environmentally friendly welding/cutting alternative during onsite construction.

The modular power unit includes an AC charging input, one or more AC power outputs, an antenna connector, an on-off selector switch, an indicator (Green/Red/Amber) or display, and a communication port.

This modular unit is adaptable to various configurations of the source, allowing for use as a portable welder, plasma cutter, or general AC power supply/generator. Each configuration would feature a distinct appearance and a customized, user-facing panel specific to its intended function. This design further facilitates straightforward OEM rebranding and customization.

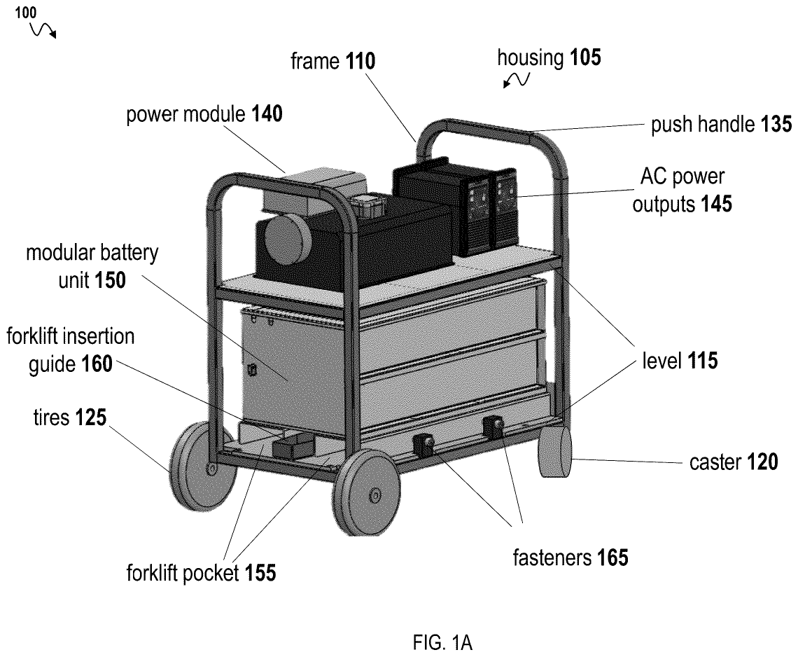

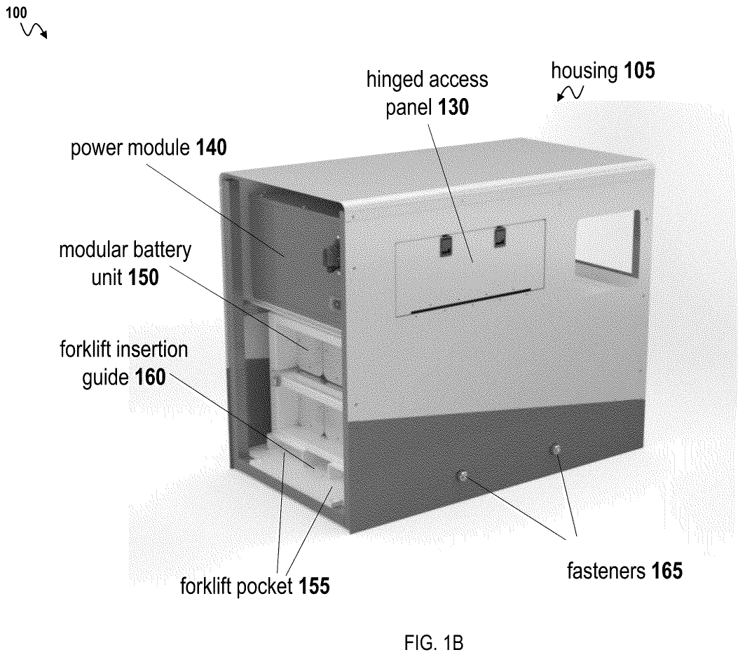

Referring now to FIGS. 1A and 1B, shown therein are a diagrams of a modular power source 100, according to an embodiment of the present disclosure.

The source 100 includes a housing 105.

The housing 105 includes a frame 110 constructed of powder-coated steel to create at least one level 115.

The housing 105 further includes two heavy-duty casters 120 attached at a first end of the frame 110.

The housing 105 further includes two airless tires 125 attached at a second end of the frame 110.

The housing 105 further includes a cooling vent system (not shown).

The housing 105 further includes a hinged access panel 130.

The housing 105 further includes a push handle 135.

The source 100 further includes a power module 140 configured for providing a variable output of power.

The power module 140 includes an AC charging input (not shown).

The power module 140 further includes a plurality of AC power outputs 145.

In some embodiments, the power module further includes at least one of an antenna connector; an on-off selector switch; a display; one or more communication ports; a battery charge monitor configured for monitoring real-time usage and accurately measuring a battery capacity; and one or more circuit breakers.

The source 100 further includes at least one modular battery unit 150.

In some embodiments, the one of more circuit breakers includes at least one of a charge circuit breaker; a push-to-reset circuit breaker; a welder circuit breaker.

In some embodiments, the display uses color to indicate a remaining battery capacity.

In some embodiments, a battery in the at least one modular battery unit 150 is one of heated; and not heated.

In some embodiments, the at least one modular battery unit 150 includes forklift pockets to facilitate removal of the at least one modular battery unit 150.

In some embodiments, the at least one modular battery unit 150 includes a forklift insertion guide 160 to facilitate removal of the at least one modular battery unit 150.

In some embodiments, the housing 105 further includes at least one fastener 165 for fastening down the at least one modular battery unit 150.

In various embodiments, the source 100 is able to communicate to an external load to provide specific usage capability.

In various embodiments, communications may be wired or wireless and configuration may be through a wireless app or touch display.

For example, in an industrial power equipment system for an industrial power equipment such as a welder, the source 100 may be used to power and communicate to one or more connected welders to retrieve the settings information and provide estimated energy usage capacity in terms of ‘welding rods’ based on the welding rod and type selected on the welder human machine interface (HMI).

In a similar industrial power equipment system for a plasma cutter, the source 100 may be used to power and communicate to one or more connected plasma cutters to retrieve their settings and provide estimated energy usage capacity in terms of linear cut length or operating time, based on the amperage, air pressure, and cutting speed settings selected on the plasma cutter HMI.

In pumped irrigation system, liquid transfer systems, or sprinkler applications, the source 100 may be used to power and communicate to one or more pump control units to retrieve settings and provide estimated energy usage capacity in terms of ‘gallons’ or ‘pump run time’.

In use with remote wireless access points and other telecom applications, the source 100 may be used to power and communicate to one or more cellular modem or satellite modem based internet access points.

For remote vehicle charging systems, the source 100 may be used to power and communicate to one or more vehicle or equipment charging stations (e.g., electric vehicle charging stations) and provides estimated energy usage capacity in terms of kWh energy supply capacity.

For a lighting system, the source 100 may be used to power and communicate to the lighting management system to retrieve their settings and provide estimated energy usage capacity in terms of ‘ON time’ based on the desired operating schedule and lighting load.

For remote monitoring, the source 100 may be used to power and communicate to the video and sensing equipment the estimated energy usage capacity in terms of ‘ON time’based on the desired operating schedule and load.

For stand-by power, in cases where secondary power is required during a mains grid failure, the source 100 may be used to temporarily power and communicate to a power grid (e.g., an isolated grid or micro-grid) and provides estimated energy usage capacity in terms of kWh energy supply capacity.

In various embodiments, the modular portable power source 100 has an integrated antenna to provide a wireless cloud connection for monitoring status and consumption and communicating load parameters to the cloud.

Both Edge-based and Cloud based AI algorithms may be utilized to process the collected data and generate control actions as well as reports for the equipment use. This AI enhancement can be utilized for process improvement, usage tracking and optimization, supply management, security, and other value-add services, not only for welders, but also for plasma cutting, irrigation, remote wireless access points/telecom, remote vehicle charging, lighting, remote monitoring, and stand-by power applications.

In various embodiments, the modular portable power source 100 includes a thermal management system.

In various embodiments, the thermal management system communicates with and controls auxiliary cooling and heating based on charging connection, state of charge, and environmental temperature sensing.

In various embodiments, the modular portable power source 100 utilizes AI to analyze the load profile and adjust inverter settings to improve conversion efficiency.

Examples of this load profile adjustment include switching to standby mode upon detection of a large gap in an independently operating load profile; or in the case of pumped irrigation or lighting, developing a dynamic load profile schedule based on seasonal schedule, and inputs such as environmental sensors and weather forecasts.

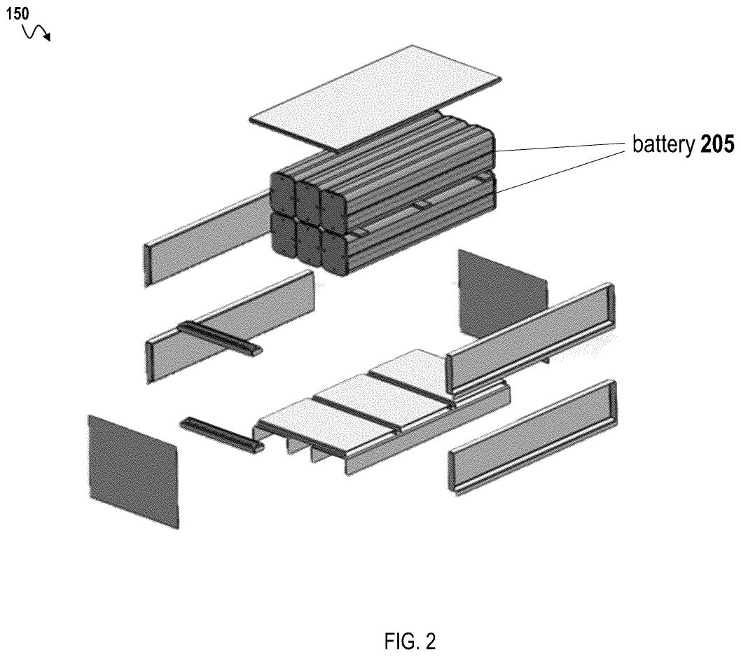

Referring now to FIG. 2, shown therein is an exploded view of the modular battery unit 150 of FIG. 1, according to an embodiment of the present disclosure.

The modular battery unit 150 may be configurable with cold climate continuous self-heating batteries 205.

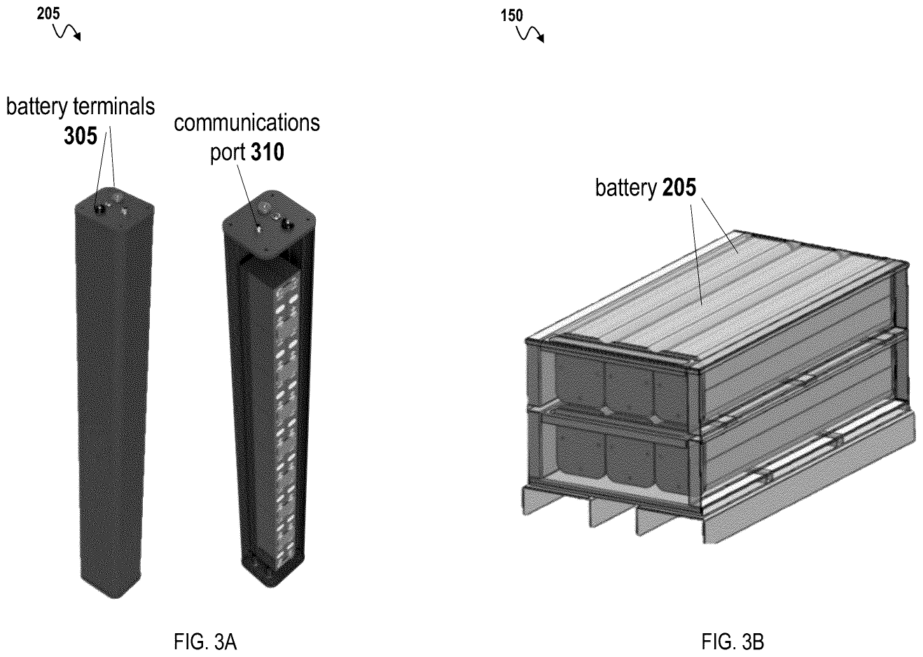

Referring now to FIG. 3A, shown therein are self-heating batteries 205, according to an embodiment of the present disclosure.

FIG. 3A depicts battery terminals 305 at the self-heating batteries 205, as well as a communications port 310 at the self-heating battery 205.

Referring now to FIG. 3B, shown therein is an alternate view of the modular battery unit 150 of FIG. 1, according to an embodiment of the present disclosure.

FIG. 3B depicts the positioning of the self-heating batteries 205 inside the modular battery unit 150.

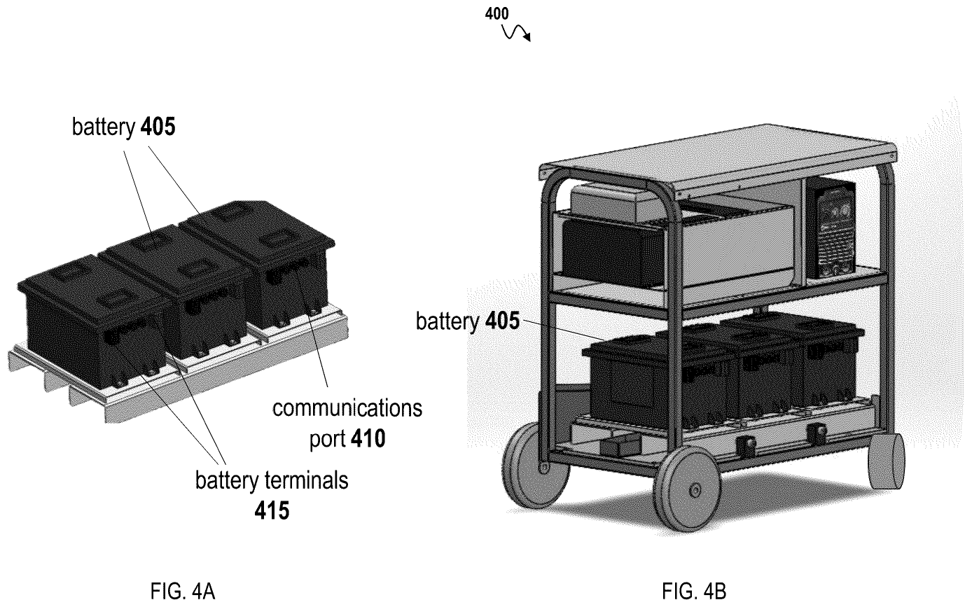

Referring now to FIG. 4A, shown therein are non-self-heating batteries 405, according to an embodiment of the present disclosure.

The non-self-heating batteries 405 include battery terminals 415 and communications ports 410.

Referring now to FIG. 4B, shown therein is a modular power source 400, according to an embodiment of the present disclosure.

This embodiment depicts the modular power source 400 with non-self-heating batteries 405.

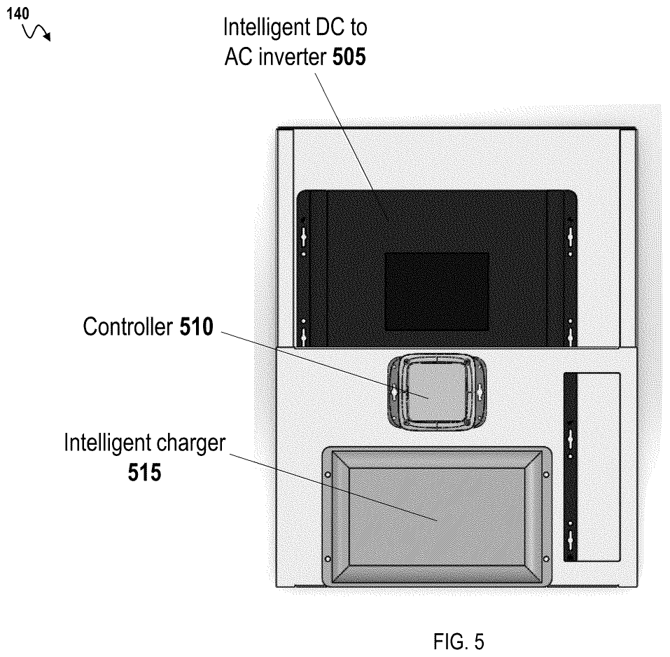

Referring now to FIG. 5, shown therein is a power module 140, according to an embodiment of the present disclosure.

The power module 140 includes an intelligent DC to AC inverter 505.

The power module 140 further includes a controller 510.

The power module 140 further includes an intelligent charger 515.

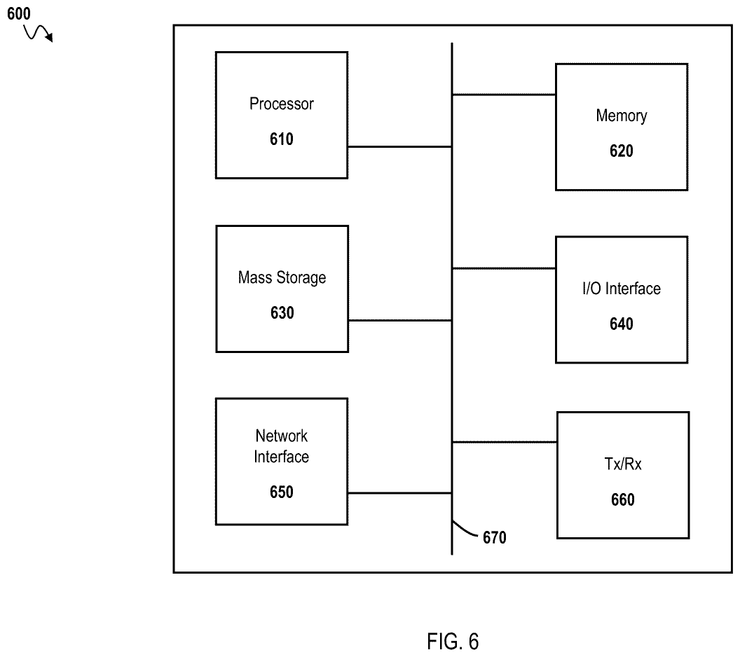

Referring now to FIG. 6, shown therein is a schematic diagram of an electronic device 600 that may perform any or all of operations of the above methods and features explicitly or implicitly described herein, according to different embodiments of the present disclosure. For example, a computer equipped with network function may be configured as electronic device 600. Furthermore, the electronic device 600 may be used to implement the controller 510 of FIG. 5, for example.

As shown, the device includes a processor 610, such as a Central Processing Unit (CPU) or specialized processors such as a Graphics Processing Unit (GPU) or other such processor unit, memory 620, non-transitory mass storage 630, I/O interface 640, network interface 650, and a transceiver 660, all of which are communicatively coupled via bi-directional bus 670.

According to certain embodiments, any or all of the depicted elements may be utilized, or only a subset of the elements. Further, the device 600 may contain multiple instances of certain elements, such as multiple processors, memories, or transceivers. Also, elements of the hardware device may be directly coupled to other elements without the bi-directional bus. Additionally, or alternatively to a processor and memory, other electronics, such as integrated circuits, may be employed for performing the required logical operations.

The memory 620 may include any type of non-transitory memory such as static random access memory (SRAM), dynamic random access memory (DRAM), synchronous DRAM (SDRAM), read-only memory (ROM), any combination of such, or the like.

The mass storage element 630 may include any type of non-transitory storage device, such as a solid state drive, hard disk drive, a magnetic disk drive, an optical disk drive, USB drive, or any computer program product configured to store data and machine executable program code.

According to certain embodiments, the memory 620 or mass storage 630 may have recorded thereon statements and instructions executable by the processor 610 for performing any of the aforementioned method operations described above.

While the above description provides examples of one or more apparatuses, methods, or systems, it will be appreciated that other apparatuses, methods, or systems may be within the scope of the claims as interpreted by one of skill in the art.

Elements of each embodiment may be incorporated into other embodiments, for example, configurations discussed in relation to one embodiment, may be applied to other embodiments disclosed herein.

Further, it is evident that various modifications and combinations can be made without departing from the invention. The specification and drawings are, accordingly, to be regarded simply as an illustration of the invention as defined by the claims, and are contemplated to cover any and all modifications, variations, combinations or equivalents that fall within the scope of the present disclosure.

1. A modular power source comprising:
a housing including:
a frame constructed of powder-coated steel to create at least one level;
two heavy-duty casters attached at a first end of the frame;
two airless tires attached at a second end of the frame;
a cooling vent system;
a hinged access panel;
a push handle;
a power module configured for providing a variable output of power, wherein the power module includes:
an AC charging input;
a plurality of AC power outputs;
at least one modular battery unit.

2. The modular power source of claim 1, wherein the power module further includes at least one of: an antenna connector; an on-off selector switch; a display; one or more communication ports; a battery charge monitor configured for monitoring real-time usage and accurately measuring a battery capacity; and one or more circuit breakers.

3. The modular power source of claim 1, wherein the one of more circuit breakers includes at least one of: a charge circuit breaker; a push-to-reset circuit breaker; a welder circuit breaker.

4. The module power source of claim 1, wherein the display uses color to indicate a remaining battery capacity.

5. The modular power source of claim 1, wherein the at least one modular battery unit is one of: heated; and not heated.

6. The modular power source of claim 1, wherein the at least one modular battery unit includes forklift pockets to facilitate removal of the at least one modular battery unit.

7. The modular power source of claim 1, wherein the at least one modular battery unit includes a forklift insertion guide to facilitate removal of the at least one modular battery unit.

8. The modular power source of claim 1, wherein the housing further includes at least one fastener for fastening down the at least one modular battery unit.

9. The modular power source of claim 1, further including an integrated antenna for wireless communications.

10. The modular power source of claim 1, further including a thermal management system.

11. A power supply system comprising:
an equipment configured to receive electrical power;
a power source configured to provide electrical power to the equipment, the power source including:
a housing including:
a frame constructed of powder-coated steel to create at least one level;
two heavy-duty casters attached at a first end of the frame;
two airless tires attached at a second end of the frame;
a cooling vent system;
a hinged access panel;
a push handle;
a power module configured for providing a variable output of power, wherein the power module includes:
an AC charging input;
a plurality of AC power outputs;
at least one modular battery unit.

12. The system of claim 11, wherein the power source is in communication with the equipment.

13. The system of claim 11, wherein the equipment includes industrial power equipment.

14. The system of claim 13, wherein the industrial power equipment includes at least one of: a welder; and a plasma cutter.

15. The system of claim 11, wherein the equipment includes at least one of: an electric vehicle; a hybrid vehicle; and a charging station.

16. The system of claim 11, wherein the equipment includes a liquid pump control unit.

17. The system of claim 11, wherein the equipment includes at least one of: a cellular modem-based internet access point; and a satellite modem-based internet access point.

18. The system of claim 11, wherein the equipment includes a lighting management system.

19. The system of claim 11, wherein the equipment includes video and sensing equipment for remote monitoring applications.

20. The system of claim 11, wherein the equipment includes a power grid.
